(19) United States
(12) Patent Application Publication
(10) Pub. No.: US 2015/0109067 A1
(43) Pub. Date: Apr. 23, 2015

(54) CONTROL DEVICE OF LC CIRCUIT USING SPIRAL INDUCTOR

(71) Applicants: Jong Hoon Park, Incheon (KR); Chang Kun Park, Suwon (KR)

(72) Inventors: Jong Hoon Park, Incheon (KR); Chang Kun Park, Suwon (KR)

(73) Assignee: SOONGSIL UNIVERSITY RESEARCH CONSORTIUM TECHNO- PARK, Seoul (KR)

(21) Appl. No.: 14/356,888

(22) PCT Filed: Apr. 12, 2012
(86) PCT No.: PCT/KR2012/002742

§ 371 Date: Sep. 5, 2014

(30) Foreign Application Priority Data
Nov. 8, 2011 (KR) 10-2011-0115758

(51) Int. Cl. H03H 11/04

(52) U.S. Cl. CPC H03H 11/04
USPC 333/17.1; 333/174

(57) ABSTRACT

Provided is a control device of a LC circuit using a spiral inductor, comprising: a spiral inductor in which a first metal line connected to a first terminal and a second metal line connected to a second terminal cross at least one time to be connected in a spiral shape, and that includes at least one crossing part; at least one transistor in which a drain terminal and a source terminal are respectively connected to a first metal line portion and a second metal line portion that correspond to the crossing part; a variable capacitor that is connected to a first terminal and a second terminal of the spiral inductor in parallel; and a controller that respectively sends control signals to the transistor and the variable capacitor to control a resonant frequency or an output.

### TECHNICAL FIELD

The present invention relates to a control device of a LC circuit using a spiral inductor, and more particularly, to a control device of a LC circuit using a spiral inductor and a variable capacitor.

### BACKGROUND ART

Nowadays, in order to quickly send large amounts of data, a radio communication frequency band has been gradually increased. Particularly, since the frequency is a finite resource, the frequency has been gradually increased up to a high frequency band that is not frequently used. When a high frequency circuit is designed, the high frequency circuit is different from an analog circuit that the high frequency circuit uses an inductor. The inductor may be used for resonance with a capacitor, and may be also used for matching, or power voltage supply.

A general inductor is formed as a coil that is wound in a spiral shape several turns. Further, two ports are formed at both ends of the coil. When the inductor is manufactured as the coil that is wound several turns, mutual inductance of the inductor may be increased. However, since inductance per unit length is increased, a Q-factor (Quality Factor) which is one of importance factors representing characteristics of the inductor is increased.

However, since it is difficult to implement the inductor as the coil in an integrated circuit, a planar inductor capable of being manufactured on a plane is used in the related art. An example of the planar inductor is disclosed in Korean Patent Publication No. 2003-0013264. Here, when the planar inductor is implemented in a spiral shape, conducting wires may be overlapped with each other, and it is required that the conducting wires are not physically overlapped with each other by using different metal layers on the integrated circuit. In general, the inductor uses the uppermost metal layer on the integrated circuit, and when the planar inductor is implemented in a spiral shape, the overlapped portion uses a layer directly below the uppermost metal layer. In this way, it is possible to easily implement an inductor wound three or more turns.

When a high frequency integrated circuit is designed, the inductor that is wound several turns has been frequently used. However, when the inductor is implemented on the integrated circuit, it is difficult to correct the integrated circuit due to its characteristic, and since a thickness of the fixed metal layer defined in the process is thick, a physical length of the manufactured inductor is changed, but it is difficult to change an inductance value of the manufactured inductor. However, a current circuit characteristic needs to be used in a broadband and multi-mode system, and the inductance value needs to be changed.

### DISCLOSURE

### Technical Problem

An object of the present invention is to provide a control device of a LC circuit using a spiral inductor capable of being implemented in multi-mode and broadband mode operations by respectively controlling the turning on or off of a transistor provided at a crossing part of the spiral inductor and capacitance of a variable capacitor connected to the spiral inductor in parallel to control a resonant frequency and an output power.

### Technical Solution

An exemplary embodiment of the present invention provides a control device of a LC circuit using a spiral inductor. The control device includes a spiral inductor in which a first metal line connected to a first terminal and a second metal line connected to a second terminal cross at least one time to be connected in a spiral shape, and that includes at least one crossing part; at least one transistor in which a drain terminal and a source terminal are respectively connected to a first metal line portion and a second metal line portion that correspond to the crossing part; a variable capacitor that is connected to a first terminal and a second terminal of the spiral inductor in parallel; and a controller that respectively sends control signals to the transistor and the variable capacitor to control a resonant frequency or an output.

Here, the spiral inductor may include two or more crossing parts, the crossing part includes a first crossing part corresponding to an outside of the spiral shape, and a second crossing part corresponding to an inside of the spiral shape, and the transistor may include a first transistor connected to both ends of the first crossing part, and a second transistor connected to both ends of the second crossing part.

Further, the controller may individually control the turning on or off of the transistors, and control capacitance of the variable capacitor.

Furthermore, when the LC circuit is in a low output mode in which a voltage is lower than a first output voltage, the controller may turn off the first transistor and the second transistor.

Moreover, when the LC circuit is in a middle output mode in which a voltage is higher than the first output voltage and is lower than a second output voltage, the controller may turn off the first transistor, and turn on the second transistor.

In addition, when the LC circuit is a high output mode in which a voltage is higher than the second output voltage, the controller may turn on the first transistor.

Furthermore, when the LC circuit operates in a high frequency higher than a first frequency, the controller may turn on the first transistor.

In addition, when the LC circuit operates in a middle frequency which is lower than the first frequency and is higher than a second frequency, the controller may turn off the first transistor, and turns on the second transistor.

Further, when the LC circuit operates in a low frequency lower than the second frequency, the controller may turn off the first transistor and the second transistor.

Moreover, the variable capacitor may be a varactor, and the controller may control such that capacitance of the varactor is low as the resonant frequency is high.

The control device may further include a detector that detects a signal at an arbitrary port included in a target circuit to which the first terminal and the second terminal are connected, and sends a control signal corresponding to a frequency or power of the detected signal to the controller.

The control device may further include a first transistor that is connected between the first terminal and a ground power supply; and a second transistor that is connected between the second terminal and the ground power supply. The variable capacitor may be connected between the first terminal and the second terminal.

The control device may further include a first transistor that is connected between the first terminal and a ground power supply. The second terminal may be connected to a DC power supply, and the variable capacitor may be connected between the first terminal and the ground power supply.

### Advantageous Effects

In accordance with a control device of a LC circuit using a spiral inductor according to the present invention, since the turning on or off of the transistor provided at the crossing part of the spiral inductor and the capacitance of the variable capacitor connected to the spiral inductor in parallel are respectively controlled to control the resonant frequency and the output power, it is possible to easily implement the spiral inductor in the multi-mode and broadband mode operations.

### DESCRIPTION OF DRAWINGS

FIG. 1 is a configuration diagram illustrating an example of a spiral inductor according to the present invention.

FIG. 2 is a configuration diagram illustrating another example of the spiral inductor according to the present invention.

FIG. 3 is a configuration diagram illustrating one embodiment of the control device of the LC circuit using the spiral inductor of FIG. 2.

FIG. 4 is a configuration diagram illustrating another embodiment of the control device of the LC circuit using the spiral inductor of FIG. 2.

### BEST MODE

Hereinafter, embodiments of the present invention will be described in detail with reference to the accompanying drawings to allow those skill in the art to easily implement the embodiments.

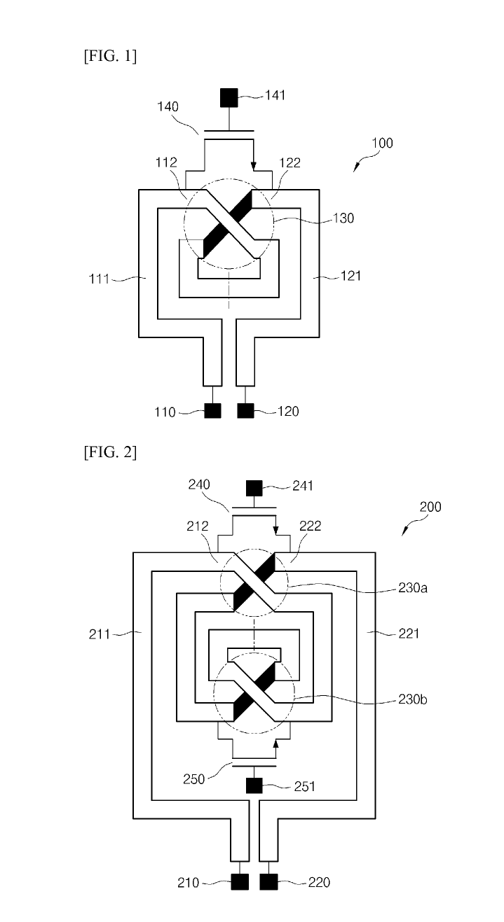

FIG. 1 is a configuration diagram illustrating an example of a spiral inductor according to the present invention. The number of turns in a spiral inductor 100 of FIG. 1 can be adjusted.

The spiral inductor 100 of FIG. 1 is a two-turn type inductor in which a first metal line 111 connected to a first terminal 110 and a second metal line 121 connected to a first terminal 120 cross each other one time and are connected in a spiral shape, and that includes one crossing part 130. The crossing part 130 is presented between an external first turn and an internal second turn. Thus, the spiral inductor of FIG. 1 is an inductor which includes the first turn and the second turn and is wound two turns.

A part (see a shaded portion) of the second metal line 121 crossing each other is formed at a different layer from a part of the first metal line 111 to prevent a short-circuit between metal layers. Here, drain and source terminals of a transistor 140 are respectively connected to a part 112 of the first metal line 111 and a part 122 of the second metal line 121 that correspond to the crossing part 130.

An operation of the spiral inductor of FIG. 1 is as follows. When a voltage is applied to a gate-side port 141 of the transistor 140, the transistor 140 operates like a short circuit. That is, when the transistor 140 operates, electric charges do not move from the part 112 of the first metal line 111 of the first turn to the metal line of the internal second turn, and directly move to the part 122 of the second metal line 121 through the transistor 140. Thus, the spiral inductor operates like a one-turn type inductor. That is, when the transistor 140 is turned on, since the part 112 of the first metal line 111 and the part 122 of the second metal line 121 are short-circuited, the internal second turn is omitted and only the external first turn remains. As a result, a one-turn type inductor in which the number of turns is one is formed.

At this time, a channel resistance of the transistor 140 exists, and in order to minimize the channel resistance, a size of the transistor is preferably large. Naturally, when no voltage is applied to a gate of the transistor 140, that is, when the transistor 140 is turned off, the spiral inductor operates like a general two-turn type inductor.

Further, when a voltage between a voltage for turning on a switch and a voltage for turning off the switch is applied to the gate of the transistor 140 used as the switch, the spiral inductor can operate like an inductor having an inductance corresponding to the number of turns between one turn and two turns.

FIG. 2 is a configuration diagram illustrating another example of the spiral inductor according to the present invention. The spiral inductor of FIG. 2 is a three-turn type inductor in which the number of turns is one-turn larger than that in the spiral inductor of FIG. 1.

The spiral inductor 200 of FIG. 2 is an inductor in which a first metal line 211 connected to a first terminal 210 and a second metal line 221 connected to a second terminal 220 cross each other two times and are connected in a spiral shape, and that includes two crossing parts, that is, a first crossing part 230a and a second crossing part 230b.

The first crossing part 230a is formed outside the spiral shape, and the second crossing section 230b is formed inside the spiral shape. More specifically, the first crossing part 230a is provided between an external first turn and an intermediate second turn, and the second crossing part 230b is provided between the intermediate second turn and an internal third turn. Accordingly, the spiral inductor is an inductor which includes the external first turn, the intermediate second turn, and the internal third turn, and is wound three turns.

A part (see a shaded portion) of the second metal line 221 and a part of the first metal line 211 that cross each other are formed at different layers from each other to prevent a short-circuit between metal layers. Here, drain and source terminals of a first transistor 240 are respectively connected to a part 212 of the first metal line 211 and a part 222 of the second metal line 221 that correspond to the first crossing part 230a. Similarly, a second transistor 250 is connected to the second crossing part 230b. That is, the first transistor 240 is connected to both ends of the first crossing part 230a, and the second transistor 250 is connected to both ends of the second crossing part 230b.

An operation of the spiral inductor of FIG. 2 is similar to that of FIG. 1. When the first transistor 240 is turned on, the number of turns in the spiral inductor 200 is changed to one regardless of the turning on or off of the second transistor 250. When the first transistor 240 is turned off and the second transistor 250 is turned on, the number of turns in the spiral inductor 200 is changed to two. Furthermore, both of the first transistor 240 and the second transistor 250 are turned off, the number of turns in the spiral inductor 200 is changed to three.

Similarly, in order to minimize a channel resistance of the transistor, a size of the transistor is preferably large. Since a size of the inductor is considerably larger than that of the transistor, there is no problem in increasing the size of the transistor.

In this way, the number of turns in the inductor can be adjusted by adjusting a gate voltage of the transistor, so that the inductance can be controlled. Accordingly, the inductor can be effectively used in a broadband and multi-mode system.

Naturally, the configuration of the spiral inductor capable of adjusting the number of turns is not necessarily limited to those of FIGS. 1 and 2. That is, the physical number of turns in the spiral inductor may be increased, and the number of the crossing parts may be two or more. Moreover, the transistor may be formed at all the crossing parts, and the transistor may be formed at only some of the crossing parts. That is, various modifications are possible without departing from the technical scope of the present invention.

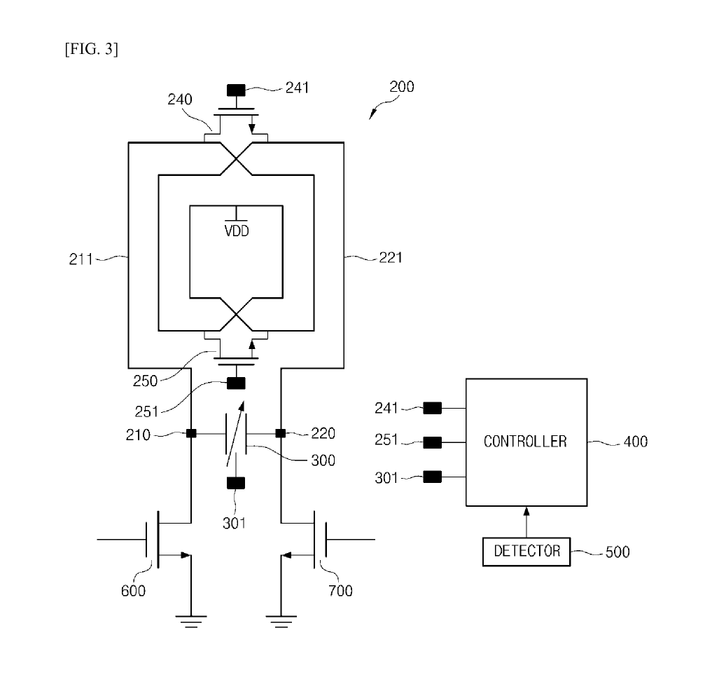

A control device of a LC circuit including the configuration of the inductor of FIG. 2 will be now described with reference to FIG. 3. FIG. 3 is a configuration diagram illustrating one embodiment of the control device of the LC circuit using the spiral inductor of FIG. 2. The control device of FIG. 3 is illustrated by more simplifying the configuration of the inductor of FIG. 2.

A configuration of a variable capacitor 300 which is connected to the first terminal 210 and the second terminal 220 of the spiral inductor 200 in parallel is included in the configuration of the control device of FIG. 3. The variable capacitor 300 may be a varactor, but the present invention is not necessarily limited thereto. The capacitor 300 is provided with a terminal 301 that receives control signals from the outside so as to vary capacitance of the capacitor by the control signals.

In addition, the control device of FIG. 3 includes a controller 400 that respectively sends the control signals to the transistors 240 and 250 and the variable capacitor 300 to control a resonant frequency or output.

The controller 400 sends signals that individually control the turning on or off of the transistors 240 and 250 to gates 241 and 251 of the transistors 240 and 250, and sends a signal that controls the capacitance of the variable capacitor 300 to send the terminal 301 of the variable capacitor 300.

A resonant frequency and an output power of the LC circuit can be controlled under the control of the controller 400. Here, since the resonant frequency can be controlled, a broadband operation can be performed, and since the output power can be controlled, a multi-mode operation can be performed.

In general, a formula of the resonant frequency is expressed as Equation 1.

f=1/2π\sqrt{LC} Equation 1

By doing this, the multi-mode operation and the broadband operation can be performed. When an inductance value and a capacitance value are small, since the denominator of Equation 1 becomes small, the resonant frequency (the operation frequency) is increased. The broadband operation can be performed using such a relation. Further, when the inductance value is controlled to be decreased and the capacitance value is controlled to be increased, the resonant frequency may be controlled so as not to be changed. At this time, since the impedance value of the inductor is changed even at the same operation frequency, the multi-mode operation can be performed by controlling the output power.

The multi-mode (the output-related) operation with the control of the controller 400 is represented in Table 1.

TABLE 1

| | First | | | |
|---|---|---|---|---|
| | transistor | | | |
| | (240) | Second | Capacitor | |
| | One-turn | transistor (250) | (300) | |
| | conversion | Two-turn | Varactor | |
| Port attribution | port | conversion port | port | Remark |
| Multi-mode | Off | Off | Low | Basic operation |
| operation (low | | | | |
| output) | | | | |
| Multi-mode | Off | On | Middle | Due to |
| operation | | | | decrease of L |
| (middle output) | | | | and increase of |
| | | | | C, fixation of |
| | | | | resonant |
| | | | | frequency and |
| | | | | increase of |
| | | | | output |
| Multi-mode | On | Don't care | High | Due to |
| operation (high | | | | decrease of L |
| output) | | | | and increase of |
| | | | | C, fixation of |
| | | | | resonant |
| | | | | frequency and |
| | | | | increase of |
| | | | | output |

When the LC circuit is in a low output mode in which a voltage is lower than a first output voltage, the controller 400 turns off the first transistor 240 and the second transistor 250. When the two transistors 240 and 250 are turned off, since the number of turns is three, the inductance is the largest, and the output is the smallest.

When the LC circuit is in a middle output mode in which a voltage is higher than the first output voltage and is lower than a second output voltage, the controller 400 turns off the first transistor 240 and turns on the second transistor 250. In this case, since the number of turns is two, the inductance is slightly decreased, and the output is slightly increased.

Furthermore, when the LC circuit is in a high output mode in which a voltage is higher than the second output voltage, the controller 400 turns on the first transistor 240. At this time, it doesn't care whether or not the second transistor 250 is turned on or off. That is, in this case, since the number of turns is one, the inductance is largely decreased, and the output is largely increased.

Here, as represented in the remark of Table 1, in the example of Table 1, when the inductance is appropriately decreased and the capacitance is appropriately increased, the resonant frequency is fixed, and only the output is changed.

The broadband mode (the frequency-related) operation with the control of the controller 400 is as Table 2.

TABLE 2

| | First | | | |
|---|---|---|---|---|
| | transistor | | | |
| | (240) | Second | Capacitor | |
| | One-turn | transistor (250) | (300) | |
| | conversion | Two-turn | Varactor | |
| Port attribution | port | conversion port | port | Remark |
| broadband | On | Don't care | Low | Due to |
| operation (high | | | | decrease of L |
| frequency) | | | | and decrease of |
| | | | | C, increase of |
| | | | | resonant |
| | | | | frequency |
| broadband | Off | On | Middle | Middle |
| operation | | | | resonant |
| (middle | | | | frequency |
| frequency) | | | | |
| broadband | Off | Off | High | Due to increase |
| operation (low | | | | of L and |
| frenquency) | | | | increase of C, |
| | | | | decrease of |
| | | | | resonant |
| | | | | frequency |

Here, the LC circuit operates in a high frequency higher than a first frequency, the controller 400 turns on the first transistor 240. At this time, since the number of turns is one, the inductance is low, and, thus, the LC circuit operates in the high frequency.

Moreover, when the LC circuit operates in a middle frequency which is lower than the first frequency and is higher than a second frequency, the controller 400 turns off the first transistor 240 and turns on the second transistor 250. At this time, since the number of turns is two, the inductance is further increased, and the LC circuit operates in the middle frequency.

In addition, when the LC circuit operates in a low frequency lower than the second frequency, the controller 400 turns off the first transistor 240 and the second transistor 250. At this time, since the number of turns is three, the inductance is further increased, and the LC circuit operates in the low frequency.

Here, it is possible to further increase a frequency controlling effect by decreasing or increasing the value of the capacitor 300 in the respective operations. That is, as the resonant frequency is increased, the controller 400 can control such that capacitance of the capacitor 300, that is, the varactor becomes small.

Table 3 is obtained by combining Tables 1 and 2. The context thereof is the same, and, thus, detailed description is not presented.

TABLE 3

| | | First | Second | |
|---|---|---|---|---|
| | | transistor | transistor | |
| | | (240) | (250) | |
| | | One-turn | Two-turn | Capacitor |
| Multi- | | conversion | conversion | (300) |
| mode | Frequency | port | port | Varactor port |
| Multi- | Broadband | Off | Off | Low-low |
| mode | operation (high | | | |
| operation | frequency) | | | |
| (low | Broadband | Off | Off | Low-middle |
| output) | operation | | | |
| | (middle | | | |
| | frequency) | | | |
| | Broadband | Off | Off | Low-high |
| | operation (low | | | |
| | frequency) | | | |
| Multi- | Broadband | Off | On | Middle-low |
| mode | operation (high | | | |
| operation | frequency) | | | |
| (middle | Broadband | Off | On | Middle-middle |
| output) | operation | | | |
| | (middle | | | |
| | frequency) | | | |
| | Broadband | Off | On | Middle-high |
| | operation (low | | | |
| | frequency) | | | |
| Multi- | Broadband | On | Don't care | High-low |
| mode | operation (high | | | |
| operation | frequency) | | | |
| (high | Broadband | On | Don't care | High-middle |
| output) | operation | | | |
| | (middle frequency) | | | |
| | Broadband | On | Don't care | High-High |
| | operation (low | | | |
| | frequency) | | | |

The controller 400 may be implemented as an analog type or a digital type. When the controller is implemented as the analog type, a detail control can be performed, and when the controller is implemented a the digital type, it is easy to integrate. Further, when the analog circuit is allowed to operate in a digital type, several ports are provided as illustrated in FIG. 3, and the detail control can be performed as the analog type.

The illustrated controller 400 is merely an example, and the control of the inductor 200 is substantially controlled by turning on or off the transistors 240 and 250, and a capacitance of the varactor 300 is controlled in a fine range. For example, a large change is performed by the inductor 200, and a final control can be finely performed through the varactor 300.

Further, a detector 500 of FIG. 3 is a part that detects a signal at an arbitrary port (an input port) included in a target circuit (a differential amplifier of FIG. 3) to which the first terminal 210 and the second terminal 220 are connected. The detector 500 generates a control signal corresponding to the detected frequency or power and sends the generated control signal to the controller 400.

That is, the control signal of the controller 400 is determined by the detector 500 at the previous stage. The detector 500 receives or detects an input signal of the target circuit or other signals and determines a signal that is sent to the controller 400.

For example, when magnitude of the signal at the input port of the target circuit is small, the detector 500 sends the control signal for operating the circuit in the low output mode to the controller 400. Furthermore, the detector may detect the frequency of the input port to control an optimal output power suitable for the corresponding frequency. To achieve this, codes or signals corresponding to the low/middle/high output mode at the respective frequencies may be previously stored in the detector 500.

The target circuit of FIG. 3 corresponds to a differential amplifier including a first transistor and a second transistor. At this time, a first transistor 600 is connected between the first terminal 210 and a ground power supply, and a second transistor 700 is connected between the second terminal 220 and the ground power supply. Moreover, the variable capacitor 300 is connected between the first terminal 210 and the second terminal 220 in parallel.

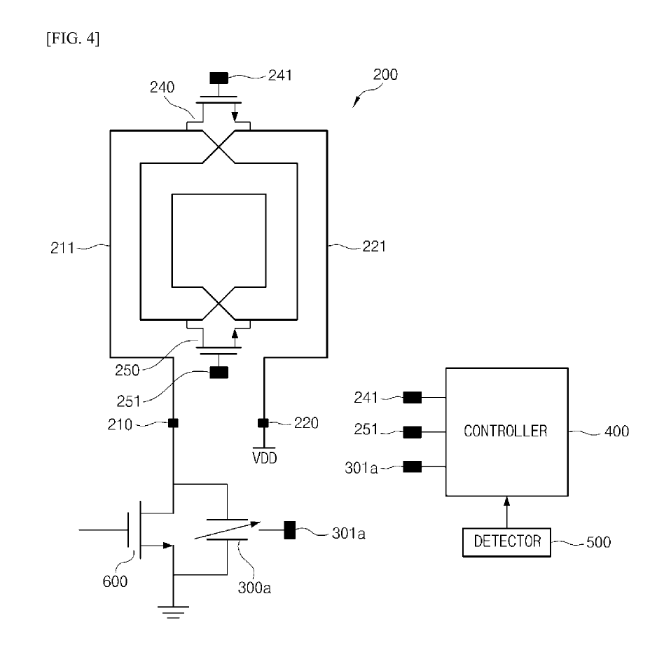

FIG. 4 is a configuration diagram illustrating another embodiment of the control device of the LC circuit using the spiral inductor of FIG. 2. In FIG. 4, the control device includes a first transistor 600 connected between the first terminal 210 and the ground power supply. That is, the target circuit of FIG. 4 is the first transistor 600. Here, the second terminal 220 may be connected to a DC power supply VDD, and a variable capacitor 300a may be connected between the first terminal 210 and the ground power supply.

In FIG. 4, the variable capacitor 300a is connected to the inductor 200 in parallel. The reason is as follows. One end of the variable capacitor 300a is connected to the first terminal 210 which is one end of the inductor 200. Further, the other end of the variable capacitor 300a is connected to the ground power supply, and the second terminal 220 which is the other end of the inductor 200 is connected to the VDD. However, in terms of AC, since the VDD is a fixed value which is not changed, the VDD is seen as a ground. Thus, the variable capacitor 300a and the inductor 200 are connected in parallel.

As described above, in accordance with the present invention, since the turning on or off of the transistor provided at the crossing part of the spiral inductor and the capacitance of the variable capacitor connected to the spiral inductor in parallel are respectively controlled to control the resonant frequency and the output power, it is possible to easily implement the spiral inductor in the multi-mode and broadband mode operations, and the spiral inductor can be applied in various circuits to be widely used.

Although the present invention has been described in connection with the embodiments illustrated in the drawings, the embodiments are merely examples. It is to be appreciated to those skilled in the art that various modifications and equivalents to these embodiments are possible. Therefore, the technical protective scope of the present invention should be decided by the technical spirit of the appended claims.

1. A control device of a LC circuit using a spiral inductor, comprising:
a spiral inductor in which a first metal line connected to a first terminal and a second metal line connected to a second terminal cross at least one time to be connected in a spiral shape, and that includes at least one crossing part;
at least one transistor in which a drain terminal and a source terminal are respectively connected to a first metal line portion and a second metal line portion that correspond to the crossing part;
a variable capacitor that is connected to a first terminal and a second terminal of the spiral inductor in parallel; and
a controller that respectively sends control signals to the transistor and the variable capacitor to control a resonant frequency or an output.

2. The control device of a LC circuit using a spiral inductor of claim 1,
wherein the spiral inductor includes two or more crossing parts,
the crossing part includes a first crossing part corresponding to an outside of the spiral shape, and a second crossing part corresponding to an inside of the spiral shape, and
the transistor includes a first transistor connected to both ends of the first crossing part, and a second transistor connected to both ends of the second crossing part.

3. The control device of a LC circuit using a spiral inductor of claim 2, wherein the controller individually controls the turning on or off of the transistors, and controls capacitance of the variable capacitor.

4. The control device of a LC circuit using a spiral inductor of claim 3, wherein when the LC circuit is in a low output mode in which a voltage is lower than a first output voltage, the controller turns off the first transistor and the second transistor.

5. The control device of a LC circuit using a spiral inductor of claim 4, wherein when the LC circuit is in a middle output mode in which a voltage is higher than the first output voltage and is lower than a second output voltage, the controller turns off the first transistor, and turns on the second transistor.

6. The control device of a LC circuit using a spiral inductor of claim 5, wherein when the LC circuit is a high output mode in which a voltage is higher than the second output voltage, the controller turns on the first transistor.

7. The control device of a LC circuit using a spiral inductor of claim 3, wherein when the LC circuit operates in a high frequency higher than a first frequency, the controller turns on the first transistor.

8. The control device of a LC circuit using a spiral inductor of claim 7, wherein when the LC circuit operates in a middle frequency which is lower than the first frequency and is higher than a second frequency, the controller turns off the first transistor, and turns on the second transistor.

9. The control device of a LC circuit using a spiral inductor of claim 8, wherein when the LC circuit operates in a low frequency lower than the second frequency, the controller turns off the first transistor and the second transistor.

10. The control device of a LC circuit using a spiral inductor of claim 4,
wherein the variable capacitor is a varactor, and
the controller controls such that capacitance of the varactor is low as the resonant frequency is high.

11. The control device of a LC circuit using a spiral inductor of claim 1, further comprising:
a detector that detects a signal at an arbitrary port included in a target circuit to which the first terminal and the second terminal are connected, and sends a control signal corresponding to a frequency or power of the detected signal to the controller.

12. The control device of a LC circuit using a spiral inductor of claim 1, further comprising:
a first transistor that is connected between the first terminal and a ground power supply; and
a second transistor that is connected between the second terminal and the ground power supply,
wherein the variable capacitor is connected between the first terminal and the second terminal.

13. The control device of a LC circuit using a spiral inductor of claim 1, further comprising:
a first transistor that is connected between the first terminal and a ground power supply,
wherein the second terminal is connected to a DC power supply, and
the variable capacitor is connected between the first terminal and the ground power supply.

14. The control device of a LC circuit using a spiral inductor of claim 5,
wherein the variable capacitor is a varactor, and
the controller controls such that capacitance of the varactor is low as the resonant frequency is high.

15. The control device of a LC circuit using a spiral inductor of claim 6,
wherein the variable capacitor is a varactor, and
the controller controls such that capacitance of the varactor is low as the resonant frequency is high.

16. The control device of a LC circuit using a spiral inductor of claim 7,
wherein the variable capacitor is a varactor, and
the controller controls such that capacitance of the varactor is low as the resonant frequency is high.

17. The control device of a LC circuit using a spiral inductor of claim 8,
wherein the variable capacitor is a varactor, and
the controller controls such that capacitance of the varactor is low as the resonant frequency is high.

18. The control device of a LC circuit using a spiral inductor of claim 9,
wherein the variable capacitor is a varactor, and
the controller controls such that capacitance of the varactor is low as the resonant frequency is high.
